(19) United States
(12) Patent Application Publication
(10) Pub. No.: US 2013/0234166 A1
(43) Pub. Date: Sep. 12, 2013

(54) METHOD OF MAKING A LIGHT-EMITTING DEVICE AND THE LIGHT-EMITTING DEVICE

(71) Applicants: Ting-Chia KO, Tainan City (TW); De-Shan KUO, Tainan City (TW)

(72) Inventors: Ting-Chia KO, Tainan City (TW); De-Shan KUO, Tainan City (TW)

(21) Appl. No.: 13/415,494

(22) Filed: Mar. 8, 2012

(51) Int. Cl. H01L 33/16; H01L 33/32

(52) U.S. Cl. 257/79; 438/33; 257/E33.003; 257/E33.001

(57) ABSTRACT

This disclosure discloses a method of making a light-emitting device. The method comprises: providing a light-emitting wafer having an orientation flat portion and comprises a substrate and a light-emitting stack formed on the substrate; forming a first line along a direction which is neither parallel nor perpendicular to the orientation flat portion; forming a second line intersecting with the first scribe line; and separating the light-emitting wafer along the first and second lines to form a plurality of light-emitting chips.

### BACKGROUND

1. Technical Field

The present disclosure relates to a method of making a light-emitting device, and in particular to separating a light-emitting wafer along the first and second lines to form a plurality of light-emitting chips.

2. Description of the Related Art

The light-emitting diodes (LEDs) of the solid-state lighting elements have the characteristics of low power consumption, low heat generation, long operational life, shockproof, small volume, quick response and good opto-electrical property like light emission with a stable wavelength, so the LEDs have been widely used in household appliances, indicator light of instruments, and opto-electrical products, etc. However, how to improve the light-emitting efficiency of light-emitting devices is still an important issue in this art.

The light-emitting device mentioned above may be mounted with the substrate upside down onto a submount via a solder bump or a glue material to form a light-emitting apparatus. Besides, the submount further comprises one circuit layout electrically connected to the electrode of the light-emitting device via an electrical conductive structure such as a metal wire.

The light-emitting device mentioned above may be mounted on a submount by one solder bump with the substrate facing up to form a flip chip type light-emitting apparatus. Besides, the submount further comprises one circuit layout electrically connected to the electrodes of the light-emitting device via the solder.

### SUMMARY OF THE DISCLOSURE

The present disclosure provides a method of making a light-emitting device.

The method comprises: providing a light-emitting wafer having an orientation flat portion and comprising a substrate and a light-emitting stack formed on the substrate; forming a first line along a direction which is neither parallel nor perpendicular to the orientation flat portion; forming a second line intersecting with the first scribe line; and separating the light-emitting wafer along the first and second lines to form a plurality of light-emitting chips.

In another embodiment of the present disclosure, a light light-emitting device is provided.

The light-emitting device comprises: a substrate comprising a substrate surface and a side surface substantially perpendicular to the substrate surface; and a light-emitting stack disposed on the substrate and comprises a sidewall substantially perpendicular to the substrate surface of the substrate. The side surface comprises a plane with a tilt angle tilted from a first miller indexed crystallographic plane of the substrate toward a second miller indexed crystallographic plane of the substrate.

In another embodiment of the present disclosure, a method of making a light-emitting device is provided.

The method of making a light-emitting device comprising: providing a light-emitting wafer comprising a semiconductor substrate and a light-emitting stack formed on the semiconductor substrate in a direction, wherein the direction is substantially perpendicular to the semiconductor substrate and the light-emitting stack, and the semiconductor substrate and the light-emitting stack have a crystal structure; and separating the light-emitting wafer along the direction to form a plurality of light-emitting chips having a sidewall parallel to the direction. The sidewall comprises a plane with a tilt angle tilted from a first miller indexed crystallographic plane of the substrate toward a second miller indexed crystallographic plane of the substrate.

### BRIEF DESCRIPTION OF THE DRAWING

The accompanying drawing is included to provide easy understanding of the application, and is incorporated herein and constitutes a part of this specification. The drawing illustrates the embodiment of the application and, together with the description, serves to illustrate the principles of the application.

FIG. 1 is a planar view of a light-emitting wafer in accordance with one embodiment of the present disclosure.

FIG. 2 is a flowchart showing a method of making the light-emitting accordance with one embodiment of the present disclosure.

FIG. 3 is a planar view of a light-emitting wafer in accordance with another embodiment of the present disclosure.

FIG. 4 is a cross-sectional view of a light-emitting chip in accordance with embodiments of the present disclosure.

FIG. 5A is an SEM image of the top-view of the light-emitting chip of the Example which is subject to a wet etching process.

FIG. 5B is an SEM image of the top-view of the light-emitting chip of the Example without wet etching process.

FIG. 5C is an SEM image of the top-view of the light-emitting chip of the Comparative Example without wet etching process.

FIG. 5D is an SEM side-view image indicated by the arrow in FIG. 5A

### DETAILED DESCRIPTION OF THE EMBODIMENTS

The following shows the description of embodiments of the present disclosure in accordance with the drawing.

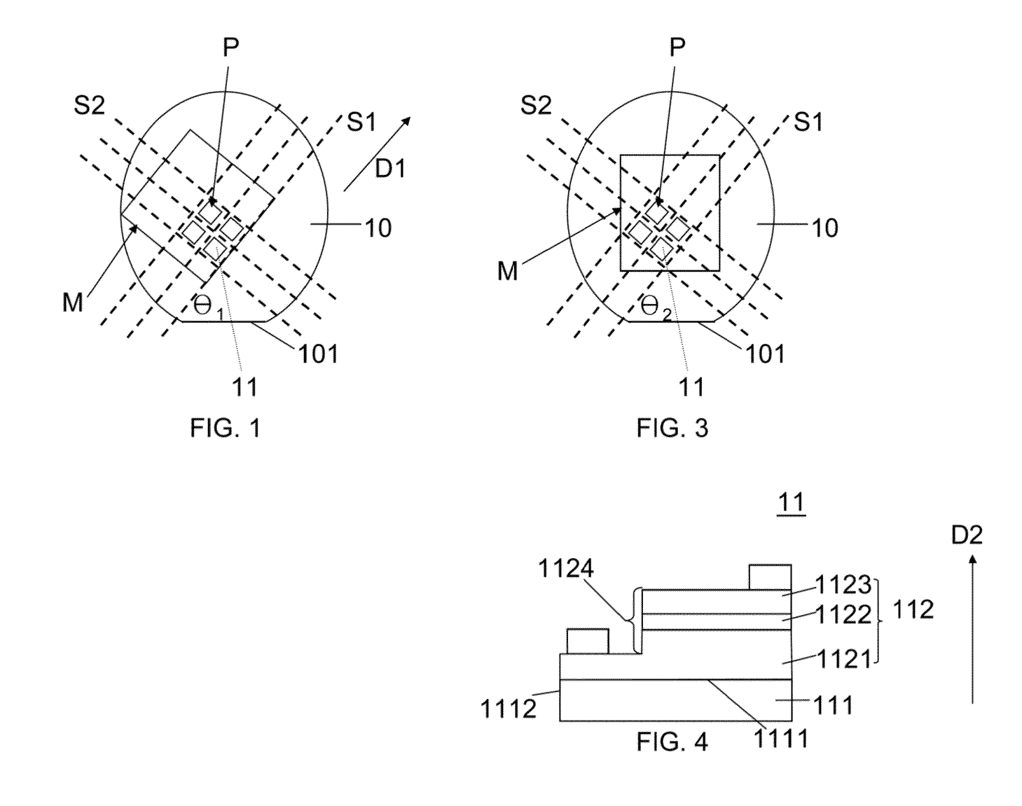

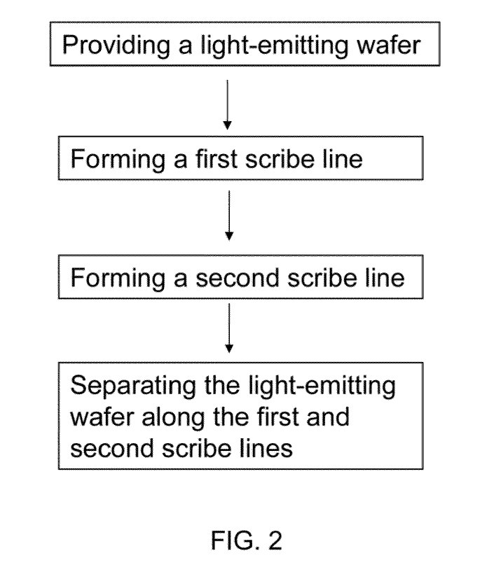

FIGS. 1 and 2 disclose a method of making a light-emitting device. The light-emitting wafer 10 is provided and has an orientation flat portion 101. A first line (S1) is formed along a first direction (D1) which is neither parallel nor perpendicular to the orientation flat portion 101 and a second line (S2) is formed to intersect with the first line (S1). Subsequently, the light-emitting wafer 10 is separated along the first and second lines (S1, S2) to form a plurality of light-emitting chips 11. In this embodiment, a rectangular mask (M) has one side arranged with respect to the orientation flat portion 101 at an angle (Θ₁) and the first and second lines (S1, S2) are defined after the photolithography process is performed on the light-emitting wafer. Thereafter, the first and second lines (S1, S2) are formed on the light-emitting wafer 10 by using a laser beam. Because the mask is arranged with respect to the orientation flat portion 101 at an angle, after forming by the laser beam, the first line is tilted from the orientation flat portion 101 at a tilt angle which is equal to the angle (Θ₁). In one embodiment, the tilt angle is greater than 0° and less than 30°. In another embodiment, the tilt angle is greater than 30° and less than 60°. The rectangular mask (M) has four sides and comprises a rectangular array pattern (P) with four sides for defining the shape of the light-emitting chip 11. Four sides of the pattern are in parallel to four sides of the mask respectively. The first line (S1) is perpendicular to the second scribe line (S2), that is, the first line (S1) is inclined with respect to the second line (S2) at an angle of 90°.

In another embodiment as shown in FIG. 3, the rectangular mask (M) has one side arranged in parallel to the orientation flat portion 101 while comprising a rectangular array pattern (P) having one side which is with respect to the orientation flat portion 101 at an angle (Θ₂). Likewise, the photolithography process is performed on the light-emitting wafer 10 to define the first and second lines (S1, S2). The first and second lines (S1, S2) are formed on the light-emitting wafer 10 by using the laser beam. Therefore, the first line (S1) is formed along the direction (D1) which is neither parallel nor perpendicular to the orientation flat portion 101, and the second line (S2) is formed to intersect with the first line (S1). The first line (S1) is tilted from the orientation flat portion 101 at a tilt angle which is equal to the angle (Θ₂). In one embodiment, the tilt angle (Θ₂) is greater than 0° and less than 30°. In another embodiment, the tilt angle (Θ₂) is greater than 30° and less than 60°.

Referring to FIG. 4, each of the light-emitting chips 11 comprises a substrate 111 and a light-emitting stack 112 formed on the substrate 111 along a second direction (D2). The second direction (D2) is substantially perpendicular to the semiconductor substrate 111 and the light-emitting stack 12. The substrate 111 has a substrate surface 1111 and a side surface 1112 substantially perpendicular to the substrate surface 1111. The light-emitting stack 112 has a sidewall 1124. The light-emitting stack 112 comprises a first-type semiconductor layer 1121, a second-type semiconductor layer 1123, and an active layer 1122 sandwiched between the first-type semiconductor layer 1121 and the second-type semiconductor layers 1123. The first-type semiconductor layer 1121, the second-type semiconductor layer 1123, and the active layer 1122 comprise a nitride-based semiconductor layer, such as GaN or InGaN. The substrate 111 comprises sapphire, GaN, ZnO, AlN, or SiC. In this embodiment, the substrate 111 comprises a hexagonal crystal structure having a miller indexed crystallographic plane aligned with the orientation flat portion 101. The miller indexed crystallographic plane has a miller index {h, i, k, l}. When h=1, i=−1, k=0, l=0, the miller indexed crystallographic plane is m-plane. When h=1, i=1, k=−2, l=0, the miller indexed crystallographic plane is a-plane. In this embodiment, the substrate surface 1111 of the substrate 111 has a crystallographic plane orientation (0, 0, 0, 1), which is c-plane. When each of the light-emitting chips 11 is formed by using the laser beam, the side surface 1112 of the substrate 111 is substantially perpendicular to the substrate surface 1111, and the sidewall 1124 of the light-emitting stack 112 is also substantially perpendicular to the substrate surface 1111. In other words, the side surface 1112 and the sidewall 1124 are parallel to the second direction (D2). Furthermore, since each of the light-emitting chips 11 is separated along the first and second lines (S1, S2) which are tilted from the orientation flat portion 101 at a tilt angle, the side surface 1112 and the sidewall 1124 substantially comprises a plane with a tilt angle tilted from a first miller indexed crystallographic plane of the hexagonal crystal structure toward a second miller indexed crystallographic plane of the hexagonal crystal structure. In one embodiment, the first miller indexed crystallographic plane has a miller indices {h₁, i₁, k₁, l₁}; h₁=1, i₁=−1, k₁=0, l₁=0; and the second miller indexed crystallographic plane has a miller indices {h₂, i₂, k₂, l₂}; h₂=1, i₂=1, k=−2, l₂=0, and the tilt angle is greater than 0° and less than 30°. In another embodiment, the tilt angle is greater than 30° and less than 60°.

In one embodiment, the first-type semiconductor layer 1121, the second-type semiconductor layer 1123, and the active layer 1122 comprise a GaP-based semiconductor layer, such as GaP, InGaP, or AlGaInP. The substrate 111 comprises GaAs and has a cubic crystal structure having a miller indexed crystallographic plane {0,1,1} aligned with the orientation flat portion 101. The substrate surface 1111 of the substrate 111 has a crystallographic plane orientation tilted from the crystallographic plane (1, 0, 0) at an angle of 15°. The side surface 1112 and the sidewall 1124 substantially comprises a plane with a tilt angle tilted from a first miller indexed crystallographic plane of the hexagonal crystal structure toward a second miller indexed crystallographic plane of the hexagonal crystal structure. In one embodiment, the first miller indexed crystallographic plane has a miller indices {a₁, b₁, c₁}; a₁=1, b₁=0, c₁=0; and the second miller indexed crystallographic plane has a miller indices {a₂, b₂, c₂}; a₂=0, b₂=1, b₂=1, and the tilt angle is greater than 0° and less than 45°. In above embodiments, the laser beam comprises stealth dicing laser or ablation laser. In one embodiment, the first and second lines (S1, S2) are formed by using a dicer, such as a diamond dicing saw.

### EXAMPLE

### Example

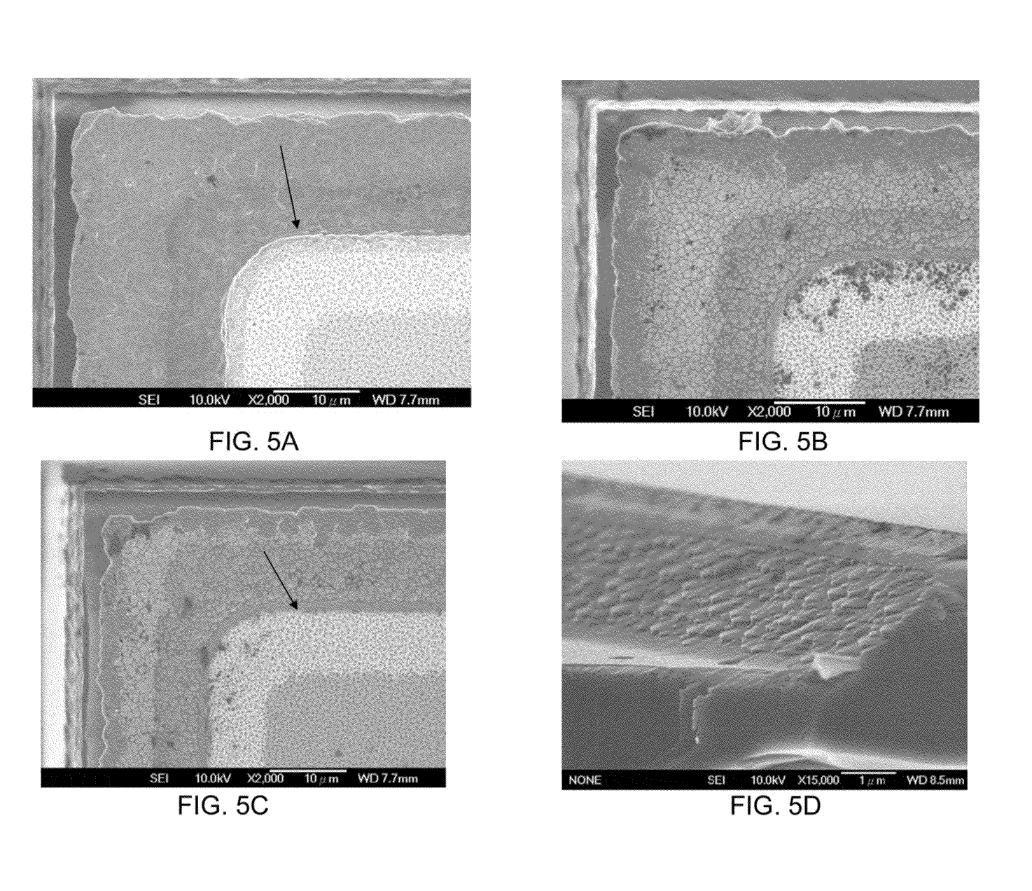

The light-emitting stack 112 is grown on the substrate 111 by epitaxial process. The mask is arranged with respect to the orientation flat portion 101 at an angle (Θ₁) of 45°. The mask has four sides and comprises a rectangular array pattern (P) with four sides, and the four sides of the pattern are in parallel to the four sides of the mask respectively. Subsequently, the photolithography process is performed on the light-emitting wafer 10 to define the first and second lines (S1, S2). A laser beam is applied to the light-emitting wafer 10 to form the first and second lines (S1, S2) in or on the substrate 111. The light-emitting wafer 10 is separated along the first and second liens (S1, S2) to form a plurality of the light-emitting chips 11. The substrate 111 is sapphire and the orientation flat portion 101 is a-plane. The light-emitting chip 11 of Example is subject to a wet etching process by KOH solution. The SEM (scanning electron microscope) image of the top-view of the light-emitting chip 11 of Example is shown in FIG. 5A. FIG. 5B is another SEM image of the top-view of the light-emitting chip 11 without being subject to the wet etching process.

### Comparative Example

A method of making the light-emitting chip of Comparative Example has similar steps with that of Example, except that the mask is arranged in parallel to the orientation flat portion 101. The first line (S1) is formed to be parallel or perpendicular to the orientation flat portion 101. The light-emitting wafer 10 is separated along the first and second liens (S1, S2) to form a plurality of the light-emitting chips 11. FIG. 5C is an SEM image of the top-view of the light-emitting chip 11 of Comparative Example which is subject to the wet etching process by KOH solution.

TABLE 1

| | Power (mw) |
|---|---|
| Example | 417.8 |
| Comparative | 410.6 |
| example | |

Table 1 shows the experimental result of the power intensity of the light-emitting chips. Compared to the Comparative Example, the light-emitting chip of Example has the power intensity of 417.8 mw, which is increased by 1.8%. By separating the light-emitting chip 11 along the first and second lines (S1, S2) which are neither parallel nor perpendicular to the orientation flat surface 101 of the light-emitting wafer 10, the light intensity can be improved. Furthermore, the light-emitting chip of Example shown in FIG. 5A has a sidewall (as indicated by the arrow in FIG. 5A) different from the light-emitting chip of Comparative Example shown in FIG. 5C. FIG. 5D is an SEM side-view image of the sidewall indicated by the arrow in FIG. 5A. According to the FIG. 5D, the sidewall of the light-emitting stack 112 has a roughened surface, and the roughness of the roughened surface is larger than the sidewall of the Comparative Example.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A method of making a light-emitting device comprising:
providing a light-emitting wafer having an orientation flat portion and comprising a substrate and a light-emitting stack formed on the substrate;
forming a first line along a direction which is neither parallel nor perpendicular to the orientation flat portion;
forming a second line intersecting with the first scribe line; and
separating the light-emitting wafer along the first and second lines to form a plurality of light-emitting chips.

2. The method of claim 1, wherein the second line is perpendicular to the first line.

3. The method of claim 1, wherein the first line is tilted from the orientation flat portion with a tilt angle greater than 30° and less than 60°.

4. The method of claim 1, wherein the first line is tilted from the flat portion with a tilt angle greater than 0° and less than 30°.

5. The method of claim 1, wherein the first and second liens are formed by a laser beam.

6. The method of claim 1, wherein the substrate comprises a crystal structure having a miller indexed crystallographic plane aligned with the orientation flat portion.

7. The method of claim 6, wherein the miller indexed crystallographic plane has a miller indices {h, i, k, l}; and wherein h=1, i=−1, k=0, l=0; or h=1, i=1, k=−2, l=0.

8. A light-emitting device comprising:
a substrate comprising a substrate surface and a side surface substantially perpendicular to the substrate surface;
a light-emitting stack disposed on the substrate and comprises a sidewall substantially perpendicular to the substrate surface of the substrate;
wherein the side surface comprises a plane with an tilt angle tilted from a first miller indexed crystallographic plane of the substrate toward a second miller indexed crystallographic plane of the substrate.

9. The light-emitting device of claim 8, wherein the substrate comprises a hexagonal crystal structure and the substrate surface of the substrate has a crystallographic plane orientation (0, 0, 0, 1).

10. The light-emitting device of claim 9, wherein the first miller indexed crystallographic plane has a miller indices {h₁, i₁, k₁, l₁}; h₁=1, i₁=−1, k₁=0, l₁=0; and the second miller indexed crystallographic plane has a miller indices {h₂, i₂, k₂, l₂}; h₂=1, i₂=1, k₂=−2, l₂=0; and wherein the tilt angle is greater than 0° and less than 30°.

11. The light-emitting device of claim 9, wherein the first miller indexed crystallographic plane has a miller indices {h₁, i₁, k₁, l₁}; h₁=1, i₁=−1, k₁=0, l₁=0; and the second miller indexed crystallographic plane has a miller indices {h₂, i₂, k₂, l₂}; h₂=1, i₂=1, k₂=−2, l₂=0; and wherein the tilt angle is greater than 30° and less than 60°.

12. The light-emitting device of claim 9, wherein the light-emitting stack comprises a plurality of nitride-based semiconductor layers.

13. The light-emitting device of claim 12, wherein the light-emitting stack comprises a hexagonal crystal structure and the sidewall comprises a plane with an tilt angle tilted from a first miller indexed crystallographic plane of the hexagonal crystal structure toward a second miller indexed crystallographic plane of the hexagonal crystal structure.

14. The light-emitting device of claim 13, wherein the first miller indexed crystallographic plane has a miller indices {h₁, i₁, k₁, l₁}; h₁=1, i₁=−1, k₁=0, l₁=0; and the second miller indexed crystallographic plane has a miller indices {h₂, i₂, k₂, l₂}; h₂=1, i₂=1, k₂=−2, l₂=0; and wherein the tilt angle is greater than 0° and less than 30°.

15. The light-emitting device of claim 13, wherein the first miller indexed crystallographic plane has a miller indices {h1, i1, k1, l1}; h1=1, i1=−1, k1=0, l1=0; and the second miller indexed crystallographic plane has a miller indices {h2, i2, k2, l2}; h2=1, i2=1, k2=−2, l2=0; and wherein the tilt angle is greater than 30° and less than 60°.

16. A method of making a light-emitting device comprising:
providing a light-emitting wafer comprising a semiconductor substrate and a light-emitting stack formed on the semiconductor substrate in a direction, wherein the direction is substantially perpendicular to the semiconductor substrate and the light-emitting stack, and the semiconductor substrate and the light-emitting stack have a crystal structure; and
separating the light-emitting wafer along the direction to form a plurality of light-emitting chips having a sidewall parallel to the direction,
wherein the sidewall comprises a plane with a tilt angle tilted from a first miller indexed crystallographic plane of the substrate toward a second miller indexed crystallographic plane of the substrate.
